(19) United States
(12) Patent Application Publication
(10) Pub. No.: US 2012/0217474 A1
(43) Pub. Date: Aug. 30, 2012

(54) PHOTONIC DEVICE AND METHOD OF MAKING THE SAME

(75) Inventors: Keyan ZANG, Singapore (SG); Soo Jin CHUA, Singapore (SG)

(73) Assignee: AGENCY FOR SCIENCE, TECHNOLOGY AND RESEARCH, Singapore (SG)

(21) Appl. No.: 13/405,874

(22) Filed: Feb. 27, 2012

Related U.S. Application Data
(60) Provisional application No. 61/446,512, filed on Feb. 25, 2011.

(51) Int. Cl. H01L 33/04

(52) U.S. Cl. 257/13; 438/22; 977/700; 257/E33.005

(57) ABSTRACT

The present invention relates to a photonic device comprising a plurality of nanostructures that extend from a substrate, each nanostructure comprising a generally longitudinal nanostructure body formed of a semiconductor material. Each nanostructure has a proximal end portion of a first crystal lattice structure and a distal end portion of a second crystal lattice structure that is expanded relative to the proximal end portion. Each nanostructure further comprises an optically active material optically associated with the distal end portion to form a heterojunction therebetween. The present invention further relates to a method of making the disclosed nanostructures.

This application is the Provisional Application Ser. No. 61/446,512 filed Feb. 25, 2011, and entitled “A Method To Produce Nanomaesh InGa/GaN Structure By Using 3-Dimensional Strain Relaxation Nanoepitaxial Growth For High Efficient LEDs and PVs,” incorporated herein by reference.

### TECHNICAL FIELD

The present invention generally relates to a photonic device and a method of making the same.

### BACKGROUND

Photonic devices have been widely used in a number of applications, such as Light emitting diodes (LEDs) and solar cell devices. LEDs, as semiconductor light sources, have many advantages such as long use life, low energy consumption, simplicity in design and low temperature sensitivity. They are also capable of reliably providing light with high brightness and operating without threshold voltage. High brightness photonic devices require high external quantum efficiency. The overall external quantum efficiency is dependent on the internal quantum efficiency (ηᵢₙₜ) and light extraction efficiency (ηₒᵤₜ). Internal quantum efficiency is influenced by non-radiative recombination caused by the threading dislocations. A strong built-in internal electric field that reduces the electron-and-hole wave function overlap also reduces internal quantum efficiency. The light extraction efficiency of the photonic devices, which is characterized by the intensity of the emitted light and indicates the quality of the photonic devices, is typically 30-35% due to the multiple internal reflections of the emitted photons at the lattices of the high refractive-index semiconductor medium.

One main technological barrier preventing obtaining highly efficient photonic devices is the large lattice mismatch between a semiconductor material (e.g. gallium nitride (GaN)) and a substrate (e.g. sapphire) which results in a vertical threading dislocation density of 10⁹ to 10¹⁰ cm⁻². Threading dislocations are known to be non-radiative recombination centers, which reduces the internal quantum efficiency of the photonic devices. Thus, eliminating the threading dislocations may be a vital step towards improving the internal quantum efficiency of the photonic devices. Furthermore, for many high photon flux applications, such as automobile headlights, the photonic devices will likely be operated at very high current densities where threading dislocations may negatively impact device lifetimes. For these reasons, it is desirable to reduce the density of threading dislocation in the photonic devices.

A reduction in the threading dislocation density has been reported for GaN heteroepitaxial films grown over SiO₂ layers in epitaxial lateral overgrowth (ELO) processes. However, the patterning in conventional ELO is on the micrometer scale and a very thick film has to be grown on the patterned template in order to obtain a continuous GaN layer after coalescence. In the ELO technique, only the regions above the mask (e.g. SiO₂) can be used as materials with a low defect density. To realize a low defect density over the whole wafer area, a two-step ELO process has been implemented in the past. However, these two-step processes are rather complicated, expensive and time consuming

Another technological barrier to overcome is the large strain field between a semiconductor layer (e.g. GaN layer) and a quantum well active layer (e.g. InGaN/GaN multiquantum wells (MQW) active layer) due to large lattice mismatch and difference in thermal coefficient of expansion between the semiconductor material and foreign substrates. Quantum well structures formed between p-n junctions are used as active regions to control the wavelength of the emitted light in the photonic devices. GaN-based materials have large piezoelectric constants in the <0001> crystal plane direction. Strain in these layers is believed to increase this piezoelectric field which tilts the potential profile and results in a red-shift of the optical emission, known as the Quantum Confined Stark Effect (QCSE). QCSE, in addition to the red-shift of the optical emission, results in low recombination efficiency and a high threshold current.

Furthermore, the random variation in the indium concentration in a commercial InGaN/GaN quantum well layer causes broadening and shift of spectral lines.

Photonic crystal structures (also known as photonic band-gap (PBG) structures) have been applied to the semiconductor layer of a photonic device such as an LED to increase the light extraction efficiency. PBG structure is a periodic dielectric structure that has a band gap that affects propagation of light by defining a certain allowed/forbidden frequency range of light. Therefore, if the energy of the emitted photons falls within the range of allowed band gap of the PBG structure of the semiconductor medium, all the emitted photons are capable of escaping from the semiconductor medium and hence the light extraction efficiency is increased. However, a problem associated with PBG structure is that the PBG structure has a much larger portion of surface area than the conventional film such that the emitted energy due to the recombination of the electrons and holes at the p-n junction is in the form of heat instead of light due to defect states on the surface of the semiconductor. Hence, there will be less photons emitted from the surface of the semiconductor which then limits the contribution of the PBG structure to the light extraction efficiency.

A nanorod array structure formed by p-n junction along one-dimensional nanorod has been proposed to improve threading dislocation. The technologies for fabricating the nanostructure include bottom-up and top-down methods. An example of the bottom-up method is to grow the nanorods selectively by using a dielectric mask as a growth mask. A catalyst may be required in the process. However, this bottom-up method is more complex compared to conventional device fabrication such as metal organic chemical vapor deposition (MOCVD). Moreover, some crystal growth, for example, the hydride vapor phase epitaxy (HVPE) or photoelectric chemistry (PEC), are not compatible with the conventional LED device fabrication. Recently, studies have shown that micro-meter or nanometer sized array LEDs fabricated by dry etching (top-down method) offer higher light output efficiencies than conventional broad area LEDs. Unfortunately, as in the conventional LEDs, many threading dislocations are produced in these micro-sized LEDs. In addition, etching may cause structural defects in the semiconductor layer. Hence, the threading dislocations and structural defects will impact on the performance of the nanostructure and LEDs containing the nanostructure.

There is a need to provide a device or structure that may be used in applications such as LEDs, solar cells, or the like, that overcomes, or at least ameliorates, one or more of the disadvantages described above.

### SUMMARY

According to a first aspect, there is provided a photonic device comprising:

a plurality of nanostructures that extend from a substrate, each nanostructure comprising:

a generally longitudinal nanostructure body formed of a semiconductor material and having a proximal end portion of a first crystal lattice structure and a distal end portion, opposite said proximal end portion, of a second crystal lattice structure that is expanded relative to the proximal end portion;

an optically active material optically associated with the distal end portion to form a heterojunction therebetween.

Advantageously, the expanded crystal lattice structure of the distal end portion is relaxed in three-dimensional directions with significantly reduced internal lattice strain as compared to the first crystal lattice structure of the proximal end portion. Accordingly, in embodiments which incorporate metal atoms in semiconductor materials (ie such as indium (In) incorporated in GaN), strain can have a large influence on the incorporation of metal atoms in the optically active layer, which affects the wavelength and efficiency of the photonic devices. Thus, strain relaxation is induced in the optically active layer by being connected with the distal end portion of the nano-structure having an expanded lattice structure. This is particularly useful in achieving highly efficient blue- and UV-LEDs.

Furthermore, the expanded lattice structure enables a more uniform incorporation of metal atoms in the semiconductor material, thereby reducing the spectrum of light emitted, or optical losses, from the optically active layer.

In one embodiment, the optically active layer is optically associated with the distal end of the nanostructures in the sense that the optically active layer is in direct contact with the distal end of the nanostructures that is composed of the semiconductor material so that a heterojunction is formed therebetween.

Advantageously, the expanded crystal lattice structure of the distal end portion is energetically unfavourable for dislocation formation (i.e. formation of a crystallographic defect or irregularity within the crystal structure). Hence, there is a reduction in the dislocation densities of the crystal structure.

Advantageously, the expanded relaxed crystal lattice structure of the distal end portion enables greater incorporation of the optically active material as compared to a non-expanded or non-relaxed crystal lattice structure similar to the first crystal lattice structure of the proximal end portion. This extends the wavelength range of the photonic device to a longer wavelength. This also increases the light emission intensity of the present photonic device relative to devices containing crystal lattice structures that are not expanded and hence not “relaxed”. Advantageously, the expanded crystal lattice structure of the distal end portion may be selected to so that it increases the light emission intensity of the photonic device by at least one fold or at least two fold or at least three fold relative to non-expanded crystal lattice structures.

Advantageously in one embodiment, the distal end portion with the expanded crystal lattice structure has a plurality of external facets of different orientations, which not only provides a greater surface area for incorporation or deposition of the optically active material but also enables the optically active material to be applied selectively to a facet of particular orientation, or to a combination of facets that are orientated differently.

According to a second aspect of the present invention, there is provided a method of forming a photonic device comprising a plurality of nanostructures that extend from a substrate, the method comprising the steps of:

providing a template formed of a semiconductor material on the substrate, the template comprising a plurality of primary generally longitudinally shaped nanostructures projecting from the substrate and being formed of semiconductor material having a first crystal lattice structure;

forming a secondary portion on each of the primary nanostructures, said secondary portions being composed of semiconductor material having a second crystal lattice structure that is expanded relative to the first crystal structure; and

forming an optically active layer of optically active material on the secondary portions of the nanostructures.

In one embodiment, step b) comprises a first stage of growing a portion of the semiconductor material having the first crystal lattice structure by nanoepitaxial growth under selected conditions to form lower sections of the secondary portions of the nano structures.

Advantageously, nanoepitaxial growth under selected conditions enables the crystal lattice structure of the semiconductor material to undergo expansion in three dimensions to release the compressive strain in the lattice structure and achieve three-dimensional relaxation. This three-dimensional relaxation results in the formation of the secondary end portions of the nanostructures with the expanded, and therefore relaxed, crystal lattice structure.

Advantageously, three-dimensional strain relaxation in the crystal lattice structure as a result of the nanoepitaxial growth may reduce threading dislocation (i.e. defect) densities in the semiconductor material.

Advantageously, three-dimension strain relaxation in the crystal lattice structure may enable greater incorporation of the optically active material in the secondary portions of the nanostructures.

Advantageously, the conditions used to grow a portion of the semiconductor material having the first crystal lattice structure may be selected to enable nanoepitaxial growth of the semiconductor material only.

Advantageously, the template comprising the primary nanostructures, being in the form of a nano-template, enables the nanometer sized nucleation and growth of the semiconductor material.

Advantageously, the conditions used to grow a portion of the semiconductor material by nanoepitaxial growth may be selected to obtain a particular shape or texture of the secondary portions of the nanostructures having the expanded crystal lattice structure.

According to a third aspect of the present invention, there is provided a light emitting diode device having a semiconductor element comprising:

a plurality of nanostructures that extend from a substrate, each nanostructure comprising:

a generally longitudinal nanostructure body formed of a semiconductor material and having a proximal end portion of a first crystal lattice structure and a distal end portion, opposite the proximal end portion, of a second crystal lattice structure that is expanded relative to the proximal end portion;

an optically active material optically associated with the distal end portion to form a heterojunction therebetween;

a layer of a semiconductor material disposed over the distal end portions of the nanostructures to form a continuous nanostructured contact surface on the semiconductor element; and

a pair of electrodes, one of the electrodes being electrically coupled to the continuous nanostructured contact surface and the other electrode being electrically coupled to the semiconductor material of the nanostructure body.

Advantageously, the semiconductor element comprising the plurality of nanostructures significantly improves the internal quantum efficiency of the light emitting diode device based on the semiconductor element.

Advantageously, the semiconductor element may be presented in the form of a semiconductor chip able to be incorporated in the light emitting diode device.

Advantageously, the layer of the semiconductor material grown over the distal end portions of the nanostructures provides a contact surface to engage a further component of the light emitting diode device.

Advantageously, the layer of the semiconductor material disposed over the distal end portions of the nanostructures provides a template for the fabrication of an ohmic contact between the semiconductor element and a metal component of the light emitting diode device.

### DEFINITIONS

The following words and terms used herein shall have the meaning indicated:

The term “epitaxy” or “epitaxial growth” is to be interpreted broadly to include a process of depositing or growing a layer of a single crystal material over another layer of a single crystal material. In instances where the overlayer of crystalline material is the same as the layer beneath, the process is referred to as ‘homoepitaxy’, and in instances where the overlayer of crystalline material is different from the layer beneath, the process is referred to as ‘heteroepitaxy’. In homoepitaxy or heteroepitaxy, the overlayer of single crystal material has one or more preferred crystallographic orientation(s) with respect to the layer beneath. The overlayer may be referred to as an ‘epitaxial film’ or ‘epitaxial layer”; and depending on the homoepitaxy or heteroepitaxy process, the overlayer may be referred to as a homoepitaxial film or layer, or a heteroepitaxial film or layer. As to the layer beneath, it may be referred to as a ‘substrate’ or ‘substrate layer’. A paper describing exemplary techniques for epitaxial growth is given in Palisaitis et. al., “Epitaxial growth of thin films”, Physics of Advanced Materials, Winter School 2008.

The terms “nanoepitaxy”, “nanoepitaxial” and grammatical variations thereof, are to be used interchangeably and to refer to epitaxy or epitaxial growth on a nanoscale.

The term “nanoscale” is to be interpreted to include any dimensions that are below about 1 μm. The term “nanostructures” as used herein, are structures comprising “nanoscale” or “submicron” features.

The term “plurality” is to be interpreted as comprising two or more units of nanostructures, for example.

The term “optically active material” as used herein refers to a semiconductor material that is able to absorb, emit or interact with light. In one embodiment, the material may be a hybrid material. For example, the optically active material may comprise a mixed metalloid (e.g. InGaAs) or a metalloid mixture (e.g. GaAs/InAs). The term “optically active material” may also refer to the optically active centre of the material, or an essential component which endows the material with a particular light absorbing, emitting or interacting property. For example, the term “optically active material” may simply refer to the indium in InGaAs or InAS in the GaAs/InAs mixture.

The term “optically active layer” as used herein refers to a layer capable of emitting or absorbing light, the layer being in contact with an end of a nanostructure in accordance with the present invention. In one embodiment, the optically active layer may comprise only one layer of an optically active material, based on which a single quantum well arrangement may be formed. In another embodiment, the optically active layer may comprise two or more layers of the optically active material, alternating between layers of a semiconductor material that has a wider band gap than the optically active material. In this embodiment, the optically active layer comprises a multi-quantum well arrangement.

The term “quantum well” is to be interpreted broadly to include any potential well or a photonic band gap structure having a discrete energy value. The quantum well is formed from two different semiconductor materials, one with a wider band gap forms barriers confining the other with a narrower band gap, e.g. the optically active material referred to hereinabove.

The term “heterojunction” as used herein refers to an interface between two different semiconductor materials. For example, a heterojunction may be a junction between a p-type and an n-type semiconductor material.

The term “three dimensional” is to be interpreted broadly to include any structures, structural features or patterns that have both lateral variations (thickness) as well as variations with depth.

The term “facet” is to be interpreted broadly to include any flat faces on a crystal structure or a geometric shape. The term “facet plane” as used herein refers to the plane of a facet on a crystal structure or geometric shape.

The term “dislocation” is to be interpreted broadly to include any crystallographic defect or irregularity within a crystal structure or on a crystal surface. Dislocations often occur during heteroepitaxy and can be divided into two types, being misfit or threading dislocations. Misfit dislocations lie in the epitaxial interface and result from the lattice mismatch between two adjacent segments (e.g. the film and the substrate). Threading dislocations lie within the epitaxial film and run from the interface through the film all the way to the film surface. Threading dislocations may be generated in response to misfit stresses at the interface and have the final configuration consisting of a misfit segment lying in the interfacial plane bounded by two segments that thread through the interface all the way to the film surface. The term ‘dislocation densities’ or grammatical variations thereof as used herein refers to the areal density of dislocations intersecting a plain (usually the free) surface, given as number per cm². In this instance, dislocation may include misfit and threading dislocations. The term ‘threading dislocation densities’ or grammatical variations there of as used herein refers to the density or densities of threading dislocations specifically, and may be expressed as number per cm².

The term “quantum efficiency” in a light-emitting photonic device, such as an LED, refers to a measure of the number of photons generated compared with the number of electrons absorbed by the device from an applied dc current. In a light-absorbing photonic device such as a photovoltaic cell, it is a measure of the number of electrons generated compared with the number of photons absorbed from radiation incident upon the device. Sometimes quantum efficiency is stated as a fraction, and sometimes as a percentage.

The term “internal quantum efficiency” in a light-emitting photonic device refers to the inherent quantum efficiency of the process occurring within the device, and is related to the fraction of electrons in the applied current that bring about generation of a photon as a result of recombination of a conduction band electron and a positive hole. Correspondingly, the internal quantum efficiency of a light-absorbing photonic device refers to the inherent quantum efficiency of the process occurring within the device, and is related to the fraction of absorbed photons that bring about generation of a conduction band electron and a positive hole as a result of excitation of an electron from the valence energy band.

The term “external quantum efficiency” in a light-emitting photonic device refers to the fraction of electrons in the applied current that bring about release of a photon into free space outside of the device. This is lower than the internal quantum efficiency because not all of the photons generated as a result of recombination of a conduction band electron and a positive hole are emitted into free space, either because of internal reflections at the surface of the device material, or because of internal absorption of the generated photon. The external quantum efficiency of a light-absorbing photonic device refers to the fraction of incident photons that bring about generation of a conduction band electron and a positive hole as a result of excitation of an electron from the valence energy band. This is lower than the internal quantum efficiency because all incident photons may not be absorbed by the device, and because some recombination of electrons and positive holes may occur.

The term “light extraction efficiency” is to be interpreted broadly to include a measure of the proportion of photons produced within a photonic device that become available for use outside of the device. Quantitatively, it is the ratio of external quantum efficiency to internal quantum efficiency. In an LED, for example, since the external quantum efficiency is always less than the internal quantum efficiency, due to internal reflections and internal absorption of photons, the extraction efficiency is less than unity. The higher the proportion of generated photons that are emitted from the device for useful purposes, the closer the value of the light extraction efficiency approaches unity.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DISCLOSURE OF OPTIONAL EMBODIMENTS

Exemplary, non-limiting embodiments of a photonic device and a method of making the same will now be disclosed.

A photonic device according to the invention comprises a plurality of nanostructures that extend from a substrate, each nanostructure comprising:

a generally longitudinal nanostructure body formed of a semiconductor material and having a proximal end portion of a first crystal lattice structure and a distal end portion, opposite said proximal end portion, of a second crystal lattice structure that is expanded relative to the proximal end portion; and

an optically active material optically associated with the distal end portion to form a heterojunction therebetween.

In one embodiment, the width of the distal end portion has larger dimension relative to the proximal end portion of the nanostructure body.

In another embodiment, while the distal end portion has a second crystal lattice structure that is expanded relative to the first crystal lattice structure of the proximal end portion, the width of the distal end portion may not have larger, or significantly larger, dimension relative to the proximal end portion. In most embodiments, however, the width of the distal end portion with the expanded crystal lattice structure would have a larger dimension relative to the proximal end portion of the nanostructure.

In one embodiment, a lower section of the distal end portion tapers outwardly from the end of the proximal end portion along a longitudinal axis of the nanostructure body.

In one embodiment, an upper section of the distal end portion tapers inwardly from the lower section towards the end of the distal end portion of the nanostructure body.

In one embodiment, the proximal end portion of the nanostructure body may be in the form of a substantially rectangular or hexagonal column having a first crystal lattice structure and a particular width dimension. In the same embodiment, the distal end portion of the nanostructure, although formed of the same semiconductor material, may have an expanded crystal lattice structure. As a result of the expanded crystal lattice structure, the distal end portion may have a lower section which gradually expands in three dimensions, and tapers outwardly from the end of the proximal end portion along a longitudinal axis of the nanostructure body. The upper section of the distal end portion is integral to the lower section. The upper section may taper inwardly from the lower section towards the end of the distal end portion of the nanostructure body.

In one embodiment, the distal end portion with the expanded crystal lattice structure may take a bulged, hexagonal shape when viewed in cross-section. In particular, the lower section of the distal end portion with the gradually expanding structure may resemble an inverted pyramid in shape when viewed in cross-section. In this embodiment, the distal end portion has an overall structure that resembles a nanomesh.

It should be appreciated that the lower section and the overall distal end portion of the nanostructure body may take other shapes or forms.

Similarly, the proximal end portion of the nanostructure body may take other shapes or forms (i.e. other than being a rectangular or hexagonal column)

In one embodiment, the distal end portion may comprise only the lower section.

Advantageously, the distal end portion may comprise both the lower section and the upper section.

Advantageously, in whichever shape or form, the expanded crystal lattice structure of the distal end portion is relaxed in three-dimensional directions with significantly reduced internal lattice strain as compared to the first crystal lattice structure of the proximal end portion. In one embodiment, as determined by Micro-Raman Spectroscopy, the strain relaxation near a surface of the distal end portion is approximately 0.4 GPa, which is a significant value.

Advantageously, the relaxed crystal lattice structure of the distal end portion makes it energetically unfavourable for dislocation formation.

Advantageously, the lower section and, particularly, the upper section of the distal end portion may have a plurality of external facets of different orientations.

In one embodiment, the upper section of the distal end portion has a substantially horizontal upper facet, disposed at the end of the distal end portion, and a plurality of tapering side facets, tapering from the lower section of the distal end portion towards the upper facet. The substantially horizontal upper facet extends along one facet plane (i.e. the <0001> crystal plane) while the tapered side facets extend along a plurality of different facet planes (along <10 1̅1> and <11 2̅2>) crystal planes, for example).

The plurality of facets not only increases the surface area of the distal end portion, but also provides facets that are orientated along different facet planes.

In forming a nanostructure of the disclosed embodiment, an optically active material may be associated with the distal end portion to form a heterojunction therebetween.

In one embodiment, a layer of the optically active material may be disposed on one or more surfaces of the distal end portion.

In one embodiment where the distal end portion comprises a plurality of facets, a layer of the optically active material may be disposed on one particular facet (or surface) of the distal end portion having a selected orientation.

Preferably, a layer of the optically active material is disposed on a plurality of the facets of the distal end portion, including facets orientated along different facet planes.

In the embodiment in which the upper section of the distal end portion has a substantially horizontal upper facet <0001> and a plurality of tapering side facets (e.g. <10 1̅1> and <11 2̅2>), a layer of the optically active material may be disposed on the upper facet as well as the on the tapering side facets. In this instance, the optically active layer may follow the contour(s) of the upper section of the distal end portion.

Advantageously, the distal end portion of the nanostructure body having a plurality of external facets of different orientations not only provides a greater surface area for incorporation or deposition of the optically active material, but also enables the optically active material to be applied selectively to a facet of particular orientation, or to a combination of facets that are orientated differently. This accordingly increases the surface area of the optically active layer formed and enables the optically active layer to be disposed on facets orientated along different facet planes.

The substantially horizontal upper facet <0001> is known to have a large piezoelectric constant, which is not desirable. Advantageously, the disclosed embodiment enables the optically active material to be deposited on a preferred semi-polar tapering side facet <10 1̅1> and on another tapering side facet <11 2̅2>, for example, in addition to the substantially horizontal upper facet <0001>.

Advantageously, the expanded (or relaxed) crystal structure of the distal end portion enables greater incorporation of the optically active material.

Advantageously, the optically active layer may be configured to function as a photonic band gap structure capable of enhancing light extraction efficiency.

In one embodiment, the optically active layer may comprise only one layer of an optically active material, based on which a single quantum well arrangement may be formed. In another embodiment, the optically active layer may comprise two or more layers of the optically active material, alternating between layers of a semiconductor material that has a wider band gap than the optically active material. In this embodiment, the optically active layer has a multi-quantum well arrangement.

The nanostructure of the disclosed embodiment may further comprise a layer of a semiconductor material in contact with and sandwiching the, or an, optically active layer of the distal end portion to thereby form a quantum well, or complete the formation of a multi-quantum well arrangement, with an adjacent surface of the distal end portion. The semiconductor material in this instance may be similar to or different from the semiconductor material forming the proximal and distal end portions of a nanostructure body of the disclosed embodiment.

The layer of the semiconductor material in contact with and sandwiching the, or an, optically active layer of the distal end portion to form a quantum well or complete the formation of a plurality of multi-quantum wells, may be referred to as the outer layer semiconductor material.

In one embodiment in which the upper section of the distal end portion has an upper facet as well as a plurality of tapering side facets, the outer layer semiconductor material may also be deposited such that it follows the contour(s) of the upper section of the distal end portion, similar to the formation of the optically active layer in this embodiment. Advantageously in this embodiment, a plurality of quantum wells or a plurality of multi-quantum wells may be formed along different facet planes of the upper section of the distal end portion. This has significant benefit to the working of the disclosed embodiment. In a further embodiment in which the semiconductor material is GaN and the quantum well is composed of GaN/InGaN, the upper facet <0001> of the distal portion may represent the c-plane of the crystal structure and selected side facets (e.g. <10 1̅1>) may represent the semi-polar plane of the crystal structure. Advantageously, by depositing an optically active layer and a further semiconductor layer which follow the contour(s) of the upper section of the distal end portion, quantum wells may be formed along the c-plane <0001>, the preferred semi-polar facet <10 1̅1>, the <11 2̅2> side facet and other side facets of the distal end portion of the nanostructure. Advantageously, this significantly enhances the internal quantum efficiency for optical recombination, and light-emission intensity (in the case of a light emitting photonic device).

In one embodiment of the disclosed invention, there is provided a plurality of nanopores disposed between the proximal end portions of adjacently disposed nanostructures. The nanopores are substantially free of any semiconductor material and assist in light extraction or absorption.

In one embodiment, the semiconductor material forming the nanostructure body may be an n- or p-type semiconductor material.

In one embodiment, the semiconductor material forming the nanostructure body may be a metalloid selected from the group consisting of Group III and Group V elements of the Period Table of Elements.

In one embodiment, the semiconductor material forming the nanostructure body may be a group III metal-arsenide or group III metal-nitride.

In one embodiment, the semiconductor material forming the nanostructure body may be a GaN.

In one embodiment, the semiconductor material may be a n-GaN (being a GaN doped with silicon or oxygen) or a p-GaN (being a GaN doped with magnesium).

In one embodiment, the optically active material may be a hybrid material.

In one embodiment, the optically active material may be made of a mix of any two semiconductor materials disclosed hereinabove.

In one embodiment, the optically active material may be a semiconductor metalloid being doped with one or more metal selected from the group consisting of Group III elements of the Period Table. For example, the optically active material may be a semiconductor metalloid (e.g. GaAs or GaN) doped with Al or In. Therefore, the optically active material may be AlGaAs, AlGaInP or InGaN, for example.

In one embodiment, the optically active material may comprise a metalloid mixture such as GaAs/InAs.

In another embodiment, the optically active material may refer to the optically active centre of the material, or an essential component which endows the material with a particular light absorbing, emitting or interacting property. For example, optically active material may simply refer to the indium in InGaAs or InAS in the GaAs/InAs mixture.

In one embodiment, the optically active material, or optically active layer, may refer to an arrangement comprising repeating units of one layer of an optically active material together with one layer of a non-optically active material. For example, the optically active material or the overall optically active layer may comprise one layer of InGaN and one layer of GaN, with such alternating combinations being repeated to form a multi-quantum well arrangement.

In one embodiment, the outer layer semiconductor material in contact with and sandwiching the, or an, optically active layer of the distal end portion to form a quantum well may be an n- or p-type semiconductor material, with the opposite polarity to the semiconductor material forming the nanostructure body of the invention.

In one embodiment, the outer layer of semiconductor material may be a Group III metal metalloid semiconductor material.

In one embodiment, the outer layer semiconductor material may be a Group III-Group V metalloid semiconductor material.

In one embodiment, the outer layer semiconductor material may be a Group III metal-arsenide or Group III metal-nitride.

In one embodiment, the outer layer semiconductor material may be a GaN.

In one embodiment, the outer layer semiconductor material may be a p-GaN or n-GaN, which has the opposite polarity to the semiconductor material forming the nanostructure body (including the distal end portion) of the disclosed embodiment.

In one embodiment, material of the substrate supporting the nanostructures is selected from the group consisting of sapphire, silicon carbide (SiC) and silicon (Si).

There is also disclosed a method of forming a photonic device comprising a plurality of nanostructures that extend from a substrate, the method comprising the steps of:

providing a template formed of a semiconductor material on the substrate, the template comprising a plurality of primary generally longitudinally shaped nanostructures projecting from the substrate and being formed of a semiconductor material having a first crystal lattice structure;

forming a secondary portion on each of the primary nanostructures, said secondary portions being composed of semiconductor material having a second crystal lattice structure that is expanded relative to the first crystal structure; and

forming an optically active layer of optically active material on the secondary portions of the nanostructures.

In one embodiment, step a) includes depositing a layer of the semiconductor material on the substrate.

In one embodiment, step a) includes configuring the layer of the semiconductor material to form a template having a plurality of nanopores disposed between the primary nano structures.

In one embodiment, configuring the layer of the semiconductor material to form a template is achieved using a nanofabrication method and subsequent etching.

In one embodiment, the nanofabrication method is selected from the group consisting of: nano-imprinting, anodized aluminium oxide mask, E-beam lithography and interference lithography.

In one embodiment, the forming step (b) comprises the step of growing semiconductor material on the ends of the primary nanostructures by nanoepitaxial growth under conditions to thereby form an expanded end portion having a second crystal lattice structure that is expanded relative to the first crystal lattice structure. Accordingly, each formed nanostructure has a proximal end portion adjacent the substrate surface and a distal end portion, opposite the proximal end portion. The optically active material is optically associated with the distal end portion to form a heterojunction therebetween.

In one embodiment, step b) comprises a first stage of growing a portion of the semiconductor material having the first crystal lattice structure by nanoepitaxial growth under selected conditions to form lower sections of the secondary portions of the nano structures.

In one embodiment, each lower section expands from a width dimension of an adjacent proximal end portion, or adjacent primary nanostructure, to a larger width dimension.

In one embodiment, to enable nucleation and growth to begin, a small amount of a semiconductor material having the first crystal lattice structure is deposited on the template.

In one embodiment, the shape or growth of the lower sections of the secondary or distal end portions of the nanostructures may be controlled by controlling nucleation so that nanoepitaxial growth may take place in nanometer scale, selectively only in or above a surface region of the template and accompanied by three dimensional strain relaxation.

In one embodiment, the nucleation and growth is controlled to only selectively happen on or surrounding a top periphery surface of a nanopore.

In one embodiment, to control the shape or growth of the lower section and ensure that nanometer sized nucleation takes place only in the surface region of the template, the depth of the nanopores is controlled to be no less than 100 nm deep. Alternatively, the aspect ratio of the nanopores (i.e. the depth to the diameter) is controlled to be larger than 1:1. For example, the aspect ratio of the nanopores may be selected from 1.5:1, 2:1, 3:1, 4:1 or 5:1 in terms of depth as compared to diameter of a nanopore or of the nanopores.

Therefore, to have three dimensional relaxation and obtain the expanded lattice structure in the present invention, it is important to ensure nanometer sized nucleation and growth. These may be achieved by creating the nano-template (i.e. template with nanopores and nano primary structures), followed by selective nanoepitaxial growth, as shown in the disclosed embodiments.

In one embodiment of the disclosed method, step b) comprises a second stage of further growth of the semiconductor material to form upper sections of the distal end portions of the nanostructures, each upper section tapering from the larger width dimension to a smaller width dimension.

In one embodiment, the controlled growth conditions used to form the lower and upper sections of the secondary portions of the nanostructures include temperature and pressure.

In one embodiment, the temperature and pressure conditions used to form the lower and upper sections of the secondary portions are the same.

In one embodiment, the temperature used to form the lower or upper sections of the secondary portions of the nanostructures may be selected from the range of about 800° C. to about 1200° C. For example, the temperature may be selected from the range of about 800° C. to about 900° C., about 800° C. to about 1000° C., about 800° C. to about 1100° C., about 900° C. to about 1000° C., about 900° C. to about 1100° C., about 900° C. to about 1200° C., about 1000° C. to about 1200° C., about 1000° C. to about 1100° C., or about 1100° C. to about 1200° C.

In one embodiment, the pressure used to form the lower or upper sections of the secondary portions of the nanostructures may be selected from the range of about 20 torr to about 250 torr. For example, the pressure may be selected from the range of from about 20 torr to about 225 torr, about 20 torr to about 200 torr, about 20 torr to about 175 torr, about 20 torr to about 150 torr, about 20 torr to about 125 torr, about 20 torr to about 100 torr, about 30 torr to about 100 torr, about 30 torr to about 130 torr, about 30 torr to about 160 torr, about 30 torr to about 190 torr, about 30 torr to about 220 torr, about 30 torr to about 250 torr, about 50 torr to about 100 torr, about 50 torr to about 150 torr, about 50 torr to about 200 torr, or about 50 torr to about 250 torr.

In one embodiment, the lower and/or upper sections of the secondary portions of the nanostructures are formed under a temperature selected from the range of from about 800° C. to about 1200° C., and a pressure selected from the range of from about 30 torr to about 220 torr.

In one embodiment, the lower and/or upper sections of the secondary portions of the nanostructures are formed under a temperature selected from the range of from about 900° C. to about 1100° C., and a pressure selected from the range of from about 50 torr to about 200 torr. Advantageously, by combining different temperature and pressure conditions, different shaped upper sections of the secondary portions, or distal end portions, of the nanostructures may be obtained.

In one embodiment, the combination of a high temperature, for example 1200° C., and low pressure, for example, 30 torr, may result in an upper section having a general rectangular shape with a flat upper facet and substantially vertical side facets.

In another embodiment, the combination of a low temperature, e.g. selected from the range of 870° C. to 930° C., and high pressure, e.g. selected from the range of from 190 torr to 220 torr, may result in pyramid shaped upper section with side facets only. Using conditions in between the temperature and pressure ranges mentioned herein would result in a truncated pyramid with a certain surface area ratio of top facet and side facet.

In one embodiment, the invert pyramid-shaped lower sections and the corresponding upper sections of an embodiment of the present invention are formed under a temperature selected from the range of from 950° C. to about 1050°, a pressure selected from the range of from 190 torr to 220 torr.

In another embodiment, the invert pyramid-shaped lower sections and the corresponding upper sections of an embodiment of the present invention are formed under a temperature selected from the range of from 950° C. to about 1050°, a pressure selected from the range of from 190 torr to 220 torr, and a trimethylgallium flow rate selected from the range of 70 sccm to 90 sccm. In a specific embodiment, the pressure may be selected from the range of from 190 torr to 210 torr. For example, the pressure used may be 200 torr.

It should be noted that one factor contributing to the two different growth configuration of the lower and upper sections may be the strain condition of the growing film or growing nanostructure. In the lower section, the film or structure is grown on a compressive GaN pedestal (i.e. the column like primary nanostructure). As growth takes place, the film or structure undergoes three dimension strain relaxation and becomes more and more relaxed. In the case of a film, after it reaches a certain thickness, the film becomes fully relaxed and growth in the upper section takes place resulting in the structure to taper upwardly. This may be due to the fact that growth on the tapered side facet (for example, <10 1̅1>) is slower than the substantially horizontal facet <0001>.

Also, the change from the lower section growth to the upper section growth may be determined by the thickness of the lower section to become fully relaxed. This in turn may depend on the width of the pedestal (i.e. the primary nanostructure). A small pedestal requires a thinner film to become fully relaxed.

In one embodiment, for full relaxation to take place, the thickness of the lower section may be in the range of from 50 nm to 100 nm for a primary nanostructure having width dimension in the range of from 100 nm to 200 nm.

In one embodiment, in step c), an optically active layer comprising the optically active material is formed on each nanostructure and the optically active layer follows the contour(s) of the distal end portion of the nanostructure.

In one embodiment, an optically active layer may be grown using the following conditions: Trimethylgallium flow rate of about 10 sccm, trimethtylindium flow rate of about 320 sccm, NH₃ flow rate of about 18000 sccm, N₂ flow rate of about 6000 sccm, pressure of about 100 torr and temperature of about 755° C. These conditions are exemplary conditions only.

In one embodiment, an optically active layer may comprise multi-quantum wells (MQW). In one embodiment, the multi-quantum wells may be formed of InGaN/GaN. In this embodiment, the MQW may be formed by: i) first growing a layer of InGaN with a growth time of about 0.4 mins; ii) the growing a layer of GaN with a growth time of about 1.2 min; and iii) repeating steps i) and ii) four times, for example, to sequentially deposit 4 pairs of InGaN/GaN layers.

In one embodiment, the disclosed method further comprises a step of providing a layer of a semiconductor material above the optically active layer. This may be to create the p-type semiconductors for device structure.

In one embodiment, the growth condition to provide the layer of semiconductor material above the optically active layer may comprise first forming an approximately 200-nm-thick GaN layer on the nanostructures at a temperature of about 1010° C. and a pressure of about 600 torr. This may be followed by an annealing process at about 800° C. for approximately 30 mins. Trimethylgallium, ammonia and Cp₂Mg may be used as source materials for Ga, N and p-dopant (which requires Mg), respectively. The growth rate of polar facet to semipolar facet may be controlled by controlling factors including, but is not limited to, the Group V to Group III element ratio (referred to as V/III ratio hereafter), temperature and pressure. Time of growth may also be a factor.

In one embodiment, the V/III ratio is nitride to gallium ratio, i.e. N/Ga ratio.

In one embodiment, the N/Ga ratio is selected from the range of from 2200 to 4400.

Embodiments of the present invention provide a method of forming a light emitting structure, the method comprising the steps of:

providing a template layer formed of a first material on a substrate, the template layer comprising an array of nanopores extending substantially across a thickness of the template layer;

growing a nanomesh layer of the first material by nanoepitaxial growth in surface areas of the template layer between the nanopores; and

forming a light emitting layer based on the first material on the nanomesh layer.

The light emitting layer may comprise multiple quantum wells (MGWs) based on the first material.

The first material may comprise GaN.

The growing of the light emitting layer may comprise controlling one or more growth condition parameters to control a shape or texture of the light emitting layer.

The growing of the light emitting layer may comprise controlling one or more growth condition parameters to control a ratio of polar planes and semipolar planes in the light emitting layer.

The template layer may be formed using one or more of a group consisting of nano-imprinting, anodized aluminium oxide, e-beam lithography and interference lithography.

The light emitting layer may be formed such that it functions as a photonic bandgap structure for enhancing a light extraction efficiency.

Embodiments of the present invention provide a light emitting structure comprising:

a template layer formed of a first material on a substrate, the template layer comprising an array of nanopores extending substantially across a thickness of the template layer;

a nanoepitaxial nanomesh layer of the first material in surface areas of the template layer between the nanopores; and

a light emitting layer based on the first material formed on the nanomesh layer.

The light emitting layer may comprise multiple quantum wells (MGWs) based on the first material.

The light emitting layer may comprise a shape or texture having polar and semipolar planes.

The nanomesh layer may exhibit an inverse pyramid-shape.

The first material may comprise GaN.

The nanopores may be substantially free of the first material.

The light emitting layer may be configured to function as a photonic bandgap structure capable of enhancing light extraction efficiency.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1(a) to FIG. 1(f) are schematic diagrams of nanoepitaxial nanomesh GaN grown on nanopore arrays of GaN substrates: FIG. 1(a) is a cross-sectional view of a substrate with an array of primary nanostructrues extending therefrom before formation of a secondary portion having an expanded crystal lattice structure; FIG. 1(b) is a cross-sectional view of the substrate of FIG. 1(a) in which a lower section of a secondary portion has been expitaxially grown on the primary nanostructrues, the lower section having an expanded crystal structure relative to the primary nanostructures; FIG. 1(c) is a cross-sectional view of the substrate of FIG. 1(b) in which an upper section of a secondary portion has been expitaxially grown on the lower section formed in FIG. 1 (b); FIG. 1(d) is a top view of FIG. 1(a); FIG. 1(e) is a top view of FIG. 1(b); and FIG. 1(f) is a top view of FIG. 1(c)

FIG. 2 is a cross-sectional view of a single nanostructure disposed on a substrate

FIG. 3 shows SEM images of the nanostructures made according to Example 1 below. FIG. 3(a) is a SEM image of a template formed of a semiconductor material. The darker hexagonal (18) represents etched holes. FIG. 3(b) is a SEM image of showing the upper sections (16″) of the secondary portions of the nanostructures, displaying six {10-11} facets. FIG. 3(c) is a SEM image of the upper sections 16″ together with GaN/InGaN MQWs. FIG. 3(d) is a cross-section SEM image of nanostructures, showing the relaxation of the compressive strained lattice. FIG. 3(e) is an enlarged view of a cross-section SEM image of a nanostructure.

FIG. 4(a) is a TEM image of the cross-section of nanoepitaxial GaN showing the reduction of threading dislocation density by two order of magnitude reduction compared to the underlying GaN. The arrow indicates the inverted inclined facet, which shows strain relaxation. FIG. 4(b) shows selected area diffraction pattern of Nanoepitaxial GaN on nanopore arrays of GaN substrate. The two sets of (01-10) indicate the relaxation of the lattice constant by nanoepitaxy.

FIG. 5(a) is photoluminescence spectra of nanomesh InGaN MQWs on nanoporous GaN and control InGaN MQWs, showing the improvement in the light emission with more indium incorporated in the nanomesh. FIG. 5(b) is an enlarged figure of 5(a) in the wavelength range of 350 nm to 380 nm.

### DETAILED DESCRIPTION OF DRAWINGS

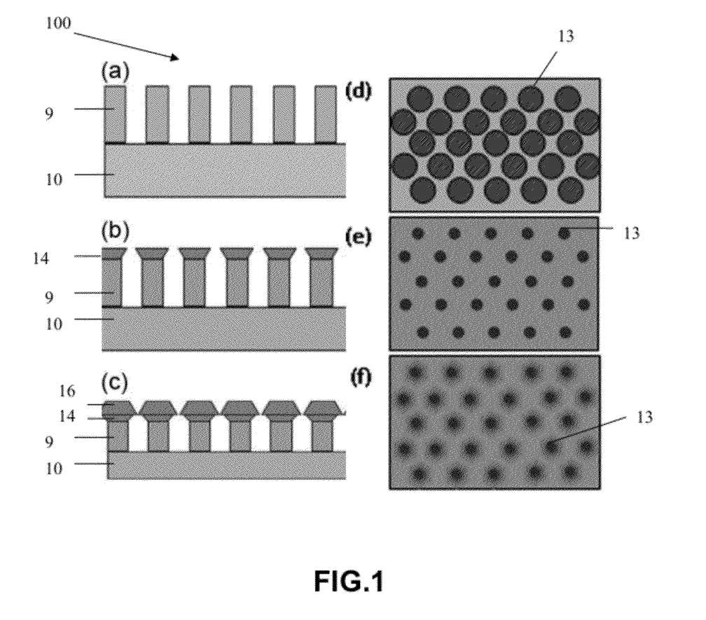

FIG. 1(a) to FIG. 1(c) are schematic diagrams showing a method of forming a photonic device 100. FIG. 1(a) shows a plurality of nanostructures 9 that extends from a substrate 10. In order to form the nanostructures 9, a template layer was first deposited on the substrate 10. The template layer was then patterned to form the nanostructures 9 seen in FIG. 1(a) using a nanofabrication method, followed by etching. The nanofabrication method is not limited and may include nano-imprinting, anodized aluminium oxide (AAO), e-beam lithography or interference lithography. The template and subsequent nanostructures 9 are made from the same material and may be a semiconductor material such as GaN. The nanostructures 9 have a first crystal lattice structure (α). FIG. 1(d) is a top view image of the photonic device of FIG. 1(a) whereby the circles 13 represent the cylindrical holes etched into the substrate 10.

In FIG. 1(b), a lower section 14 of secondary portions in the form of inverse pyramid shaped structures were formed on the nanostructures 9. The lower section 14 was grown by nanoepitaxial growth to form the inverse pyramid shape as shown in FIG. 1(b). The secondary portions were made of a semiconductor material such as GaN having a second crystal lattice structure (β) that is expanded relative to the first crystal structure (α). FIG. 1(e) is a top view image of the photonic device of FIG. 1(b), which shows that the nanostructures 9 as represented by circles 13 have been partially covered by the lower section 14 with the expanded crystal structure.

In FIG. 1(c) an upper section 16 of the secondary portions was formed on the lower section 14 of the secondary portions. The upper section 16 were grown by nanoepitaxial growth on the top of the lower section 14 as shown in FIG. 1(c). FIG. 1(f) is a top view image of the photonic device of FIG. 1(c), which shows that the nanostructures 9 as represented by the circles 13 were covered by the upper section 16 of the secondary portions.

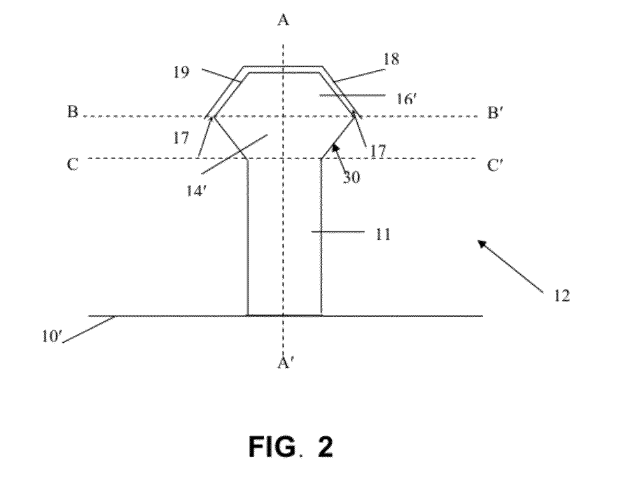

FIG. 2 shows a cross-sectional view of a single nanostructure 9′ disposed on a substrate 10′, in which the nanostructure 9′ has a number of technical features that are the same as those described in FIG. 1(c) above which are indicated by the same reference numeral but with a prime symbol (′). The nanostructure 9′ has a stem 11 and a hexagonally-shaped secondary portion 30 in the form of a lower section 14′ and an upper section 16′. Dashed lines AA′ represents the longitudinal axis passing through the nanostructure 9′. The dashed lines BB′ and CC′ represent respective cross-sectional planes that are normal relative to the longitudinal axis AA′. Dashed lines BB′ represents the point at which the upper section 16′ meets with the lower section 14′ while dashed lines CC′ represents the point at which the lower section 14′ meets with the stem 11. The stem 11 and secondary portion 30 are made of GaN.

An optically active layer 19 was formed on the surface of upper section 16′ and was composed of InGaN. Hence, a heterojunction was formed between layer 19 and upper section 16′ as shown by arrow 17. A semiconductor layer 18 was then deposited on top of the optically active layer 19 and serves to cover the nanostructure 9′. The semiconductor layer 18 was formed of GaN doped with Mg.

Advantageously, the shape and arrangement of the optically active layer 19 follows the contour or morphology of that of upper section 16′. The ratio of the semipolar plane to polar plane can be controlled by controlling the V/III ratio, pressure and temperature during the growth of the lower section 14′ and the upper section 16′.

### EXAMPLE 1

The method as shown in FIG. 1(a) to FIG. 1(c) was used to form the photonic device in this example.

GaN Template Preparation

First, GaN template was grown using metal-organic chemical vapour deposition (MOCVD) in an EMCORE-D125 system. Trimetylgallium (TMGa), trimethylaluminum (TMGa), trimethylaluminum (TMAl), and ammonia were used as source materials for Ga, Al, and N, respectively. A 30-nm-thick GaN layer was first grown on c-plane sapphire substrate at 530° C. at a total pressure of 200 torr. This was followed by the growth of a 1.5 μm GaN layer grown at a total pressure of 200 torr at 1010° C.

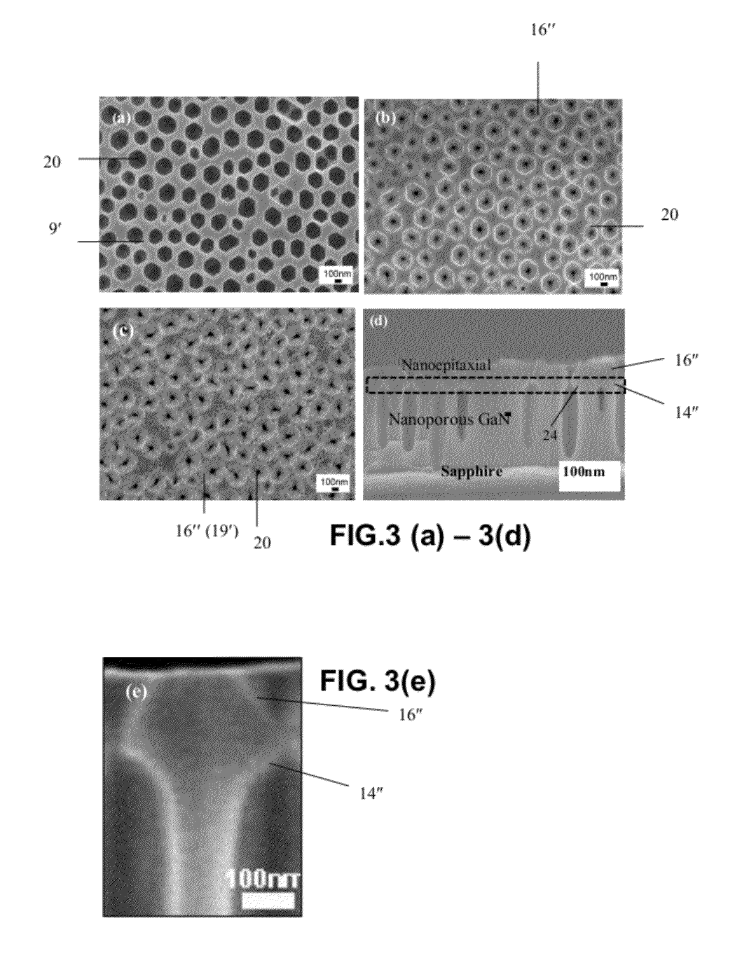

A GaN template as shown in FIG. 1(a) was fabricated by etching the GaN wafer by Inductive Coupled Plasma (ICP) using anodic alumina (AAO) as a mask. The AAO mask was created by using 0.3M phosphorus acid as electrolyte, anodized at a voltage of 150V. After formation of the GaN template, a further step was included to widen the pores 13 of FIG. 1(d) and to remove the barrier layer (not shown) in the nanopores 13. After the pore widening process, anodized alumina showed arrays of hexagonal pores 20 (as shown in FIG. 3(a) with a diameter of 200 nm and interpore distance of 300 nm. Subsequently, ICP was used to transfer the pore arrays in AAO into the GaN wafer. After the etching, the AAO mask was removed, and the obtained nanoporous GaN template (as shown in FIG. 3(a)) was cleaned and then loaded into the MOCVD reactor.

Secondary Portion and Quantum Well Preparation

A ˜200 nm GaN layer was deposited on the nanoporous GaN template at 1010° C. using H₂ as carrier gas. The growth time was precisely controlled in order to produce a plurality of nanostructures 12 of FIG. 2 (without the optically active layer 19). a. Four periods of InGaN/GaN multiquantum-wells (MQW) were then grown on the nanoepitaxial GaN at a temperature of 755° C. and chamber pressure of 100 Torr, to form an optically active layer 19 as shown in FIG. 2. Trimethylgallium (TMGa), trimethylindium (TMIn), and NH₃ were used as the source for Ga, In, and N, respectively. During the growth of the GaN layer, TMGa flow rate of about 80 sccm, NH₃ flow rate of about 12000 sccm, H₂ flow rate of about 6000 sccm, a pressure of about 200 torr and a growth time of about 9.5 mins were applied. Nitrogen was used as the carrier gas for the InGaN/GaN quantum well growth. For InGaN/GaN MQWs growth, TMGa flow rate of about 320 sccm, NH₃ flow rate of about 18000 sccm, N₂ flow rate of about 6000 sccm and a pressure of about 100 torr were used. To grow InGan/GaN MQWs, a layer of InGaN with growth time of 0.4 mins was grown followed by a layer of GaN with growth time of 1.2 mins. Four pairs of InGaN/GaN layers were sequentially deposited. A nonpatterned GaN epilayer was also loaded into the MOCVD chamber to be grown simultaneously as a reference sample.

Results (1): FIG. 3a shows the top view SEM image of the GaN template. The GaN template was fabricated by ICP etching. The darker hexagon 20 represents etched holes. The average diameter of the hexagon 20 was ˜200 nm with an average inter-distance of ˜300 nm. The height of the primary nanostructures 9″ was ˜800 nm. FIG. 3b and FIG. 3c show the top view SEM images of the secondary portions, in particular the upper sections (16″), of nanoepitaxial GaN nanostructures and the optically active layer 19′ comprising InGaN MQWs. The secondary portions of the nanoepitaxial GaN demonstrated nanomesh structures with six {10-11} facets. The optically active layer 19′ comprises InGaN MQWs which follow the same morphology as the upper sections 16″ of the secondary portions. FIG. 3d shows the cross-sectional SEM image of nanoepitaxial GaN. It was observed that the secondary portions comprising nanoepitaxial GaN was grown on top of the nanoporous GaN template containing primary nanostructure 9′. No deposition within the pores was observed. The inverted inclined facet is present on the lower section 14″ of the secondary portions (14″ and 16″) between the dashed lines as shown in FIG. 3d, which indicates the relaxation of the compressively strained lattice by nanoepitaxy. The expanded crystal lattice structure of the lower section 14″ may be better seen in the enlarged FIG. 3(e).

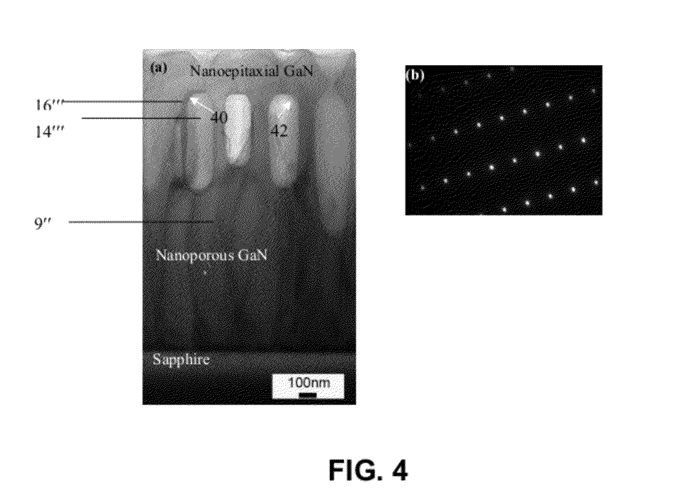

Results (2): To further understand the microstructure, the strain relaxation and the defects in nanoepitaxial GaN, XTEM had been employed. A XTEM image of nanoepitaxial GaN is presented in FIG. 4a. The presence of the primary nanostructure 9′″ had an obvious effect on the dislocation behaviours in the secondary portions 14′″ and 16′″. The dislocation density in the nanoepitaxial secondary portion was greatly reduced compared to the underlying primary nanostructure 9′″ in the GaN template. The estimated threading dislocation density in the secondary portions (14′″ and 16′″) nanoepitaxial GaN was reduced by two orders of magnitude (10⁸ cm⁻²) from that of the primary nanostructure 9′″ in the GaN template (10¹⁰ cm⁻²). Nanometer sized nucleation and growth was one of the reasons for low defect density in nanoepitaxial GaN.

The estimated threading dislocation density in the nanoepitaxial GaN is reduced by two orders of magnitude (10⁻⁸ cm⁻²) from that of the template (10⁻¹⁰ cm⁻²). The dislocation density was achieved by counting the surface pits in FIG. 4, since the surface pits are the ends of the threading dislocations in the crystal structure.

It was observed that an inverted inclined facet occurred at the initial growth stage of the lower section 14′″ of the secondary portions (14′″ and 16′″) as indicated by the arrows 40 & 42 in FIG. 4a. It showed the relaxation of the compressive strain in the underlying GaN template. Theoretically, growth in the nanoscale allowed the epilayer to relax in three-dimensional in response to lattice mismatch. Here, due to the nanogrowth, the lattice of the secondary portions 14′″ and 16′″ nanoepitaxial GaN underwent expansion to release the compressive strained lattice. FIG. 4b shows the selected area diffraction pattern of nanoepitaxial GaN. The image demonstrates 2 sets of (01-10) planes which indicate the relaxation of the lattice by nanoepitaxy.

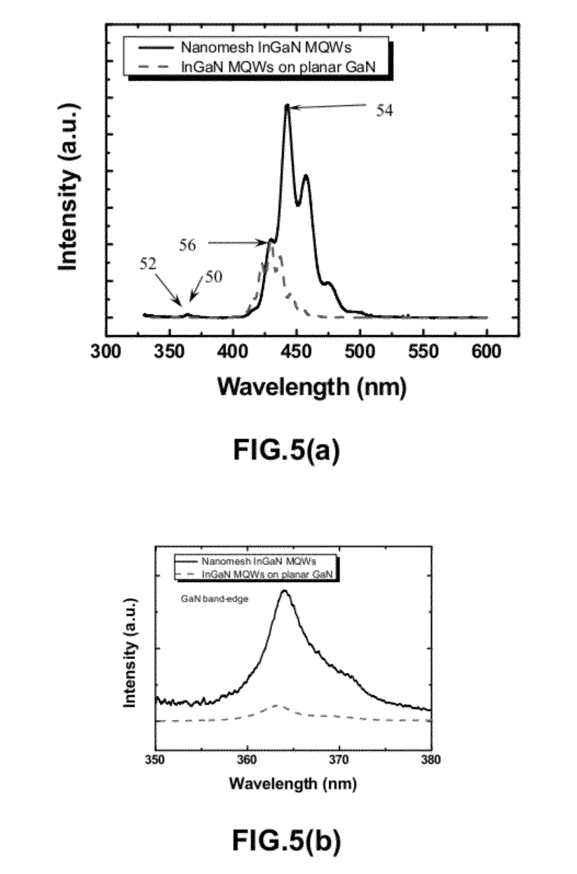

Results (3): FIG. 5(a) shows the room temperature photolouminescence spectra for nanomesh InGaN MQWs and that of the control sample. FIG. 5(b), which is an enlarged view of the wavelength range 350 nm-380 nm of FIG. 5(a), shows the band-edge peaks of GaN are centred at 366.7 (50) nm and 363.5 nm (52) for nanorod film. The red-shifted GaN band-edge photoluminescence peak from the patterned sample further supports the relaxation of compressive stress. Strong emission around 450 nm (54) was observed from the nanomesh InGaN MQWs. The intensity from the nanomesh InGaN MQWs was observed to be 3 times higher compared to that of the control InGaN MQWs (56). The improvement in light emission was due to the reduction in the number of nonradiative recombination centers associated with TDs. More importantly, better light extraction from the nano-structures played a more important role in the enhancement of the PL emission. In addition, nanomesh InGaN MQWs demonstrated that the emission peak from the nanomesh MQWs was red-shift ˜16 nm compared to that of the control MQWs sample. This was partially due to more indium incorporation in the MQWs nanorods. It had been reported that the strain in the GaN layer had an obvious effect on the indium incorporation during the InGaN growth. A fully relaxed sample was able to incorporate more indium during growth than a strained sample. In this example, as shown previously, a significant strain relaxation had been demonstrated. This strain relaxation in the nanostructures allowed for a better lattice mismatch between the barrier and the designated well growth and hence higher indium incorporation as the indium atom was larger than the Ga atom.

In conclusion, a method to fabricate low defects and strain released nanomesh GaN based nanostructures by combining top-down and bottom-up technique is described. The method utilizes the reduction of threading dislocations and 3D relaxation of strain during nanoepitaxy to produce GaN nanomesh with high quality. This method is beneficial for high efficient light emitting diodes and solar cells in five ways: (1) effectiveness in reducing the threading dislocation densities to enhance internal quantum efficiency; (2) light is scattered at the nanoporous interface which enhances the light extraction efficiency; (3) ability to expand wavelength range of GaN-based structures towards longer wavelength due to more indium incorporation in the nanomesh structures; (4) compatible with current MOCVD and device fabrication process; and (5) substantially free of strain with low piezoelectric field in the nanomesh structures, which results in higher internal quantum and recombination efficiency. This enables the fabrication of high efficiency and high power LEDs and PVs. The disclosed nanomesh structures provide for a novel and direct way to produce various visible, white and ultraviolet LEDs with high efficiency and brightness for the full color display and general lighting applications.

### APPLICATIONS

The photonic device and embodiments disclosed herein may be used as a light-emitting device (such as a LED) or a light-absorbing device (such as a solar cell).

Advantageously, the disclosed photonic device with the nanostructures having an expanded and relaxed crystal lattice structure have at least ameliorated the problems associated with a conventional device, problems such as dislocations and limited incorporation of an optically active material due to the strained lattice structure.

Advantageously, the disclosed photonic device has significantly improved internal and external quantum efficiencies due to the nanostructures having a first crystal lattice structure and a second, expanded crystal lattice structure.

Advantageously, an embodiment of the disclosed photonic device as shown in the Examples has shown a three-fold increase in light emission intensity.

The method disclosed herein facilitates nanoepitaxial growth of a semiconductor material to form the disclosed photonic device with nanostructures having an expanded crystal lattice structure.

In one aspect, the disclosed method facilitates the formation of photonic devices having a faceted optically active layer with enhanced incorporation of an optically active material.

Advantageously, the disclosed method provides the disclosed photonic device with overall enhanced photonic properties.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

What is claimed:

1. A photonic device comprising:
a plurality of nanostructures that extend from a substrate, each nanostructure comprising:
a generally longitudinal nanostructure body formed of a semiconductor material and having a proximal end portion of a first crystal lattice structure and a distal end portion, opposite said proximal end portion, of a second crystal lattice structure that is expanded relative to the proximal end portion;
an optically active material optically associated with the distal end portion to form a heterojunction therebetween.

2. The photonic device as claimed in claim 1, wherein the width of the distal end portion has larger dimension relative to the proximal end portion of the nanostructure body.

3. The photonic device as claimed in claim 2, wherein a lower section of the distal end portion tapers outwardly from the end of the proximal end portion along a longitudinal axis of the nanostructure body.

4. The photonic device as claimed in claim 2, wherein an upper section of the distal end portion tapers inwardly from the lower section towards the end of the distal end potion of the nanostructure body.

5. The photonic device as claimed in 1, wherein a layer of the optically active material is disposed on one or more surfaces of the distal end portion.

6. The photonic device as claimed in claim 5, wherein a layer of the optically active material is disposed on a surface of the distal end portion with a selected orientation.

7. The photonic device as claimed in claim 5, wherein each nanostructure further comprises a layer of a semiconductor material in contact with and sandwiching the, or an, optically active layer of the distal end portion.

8. The photonic device as claimed in 1, wherein a plurality of nanopores are disposed between the proximal end portions of the adjacently disposed nanostructures.

9. The photonic device as claimed in 1, wherein the semiconductor material forming the proximal and distal end portions of the nanostructures is a metalloid.

10. The photonic device as claimed in 1, wherein the optically active material is a semiconductor metalloid being doped with a metal selected from Group III of the periodic table.

11. The photonic device as claimed in claim 9 or 10, wherein the layer of the semiconductor material in contact with and sandwiching the optically active layer is a metalloid having an opposite polarity to the metalloid forming the proximal and distal end portions of the nanostructures.

12. A method of forming a photonic device comprising a plurality of nanostructures that extend from a substrate, the method comprising the steps of:
providing a template formed of a semiconductor material on the substrate, the template comprising a plurality of primary generally longitudinally shaped nanostructures projecting from the substrate and being formed of a semiconductor material having a first crystal lattice structure;
forming a secondary portion on each of the primary nanostructures, said secondary portions being composed of semiconductor material having a second crystal lattice structure that is expanded relative to the first crystal structure; and
forming an optically active layer of optically active material on the secondary portions of the nanostructures.

13. The method according to claim 12, wherein step b) comprises a first stage of growing a portion of the semiconductor material having the first crystal lattice structure by nanoepitaxial growth under selected conditions to form lower sections of the secondary portions of the nanostructures.

14. The method according to claim 13, wherein step b) comprises a second stage of further growth of the semiconductor material to form upper sections of the secondary portions of the nanostructures.

15. The method according to claim 13 or 14, wherein the lower or upper sections are formed under a temperature selected from the range of from about 900° C. to about 1100° C., and a pressure selected from the range of from about 50 torr to about 200 torr.

16. The method according to claim 12, wherein step a) includes a step of configuring the template to form a plurality of nanopores disposed between the primary nano structures.

17. The method according to claim 16, wherein configuring the layer of the semiconductor material to form a template is achieved using a nanofabrication method and subsequent etching.

18. The method according to claim 17, wherein the nanofabrication method is selected from the group consisting of: nano-imprinting, anodized aluminium oxide mask, E-beam lithography and interference lithography.

19. The method according to claim 12 further comprising a step of providing a layer of a semiconductor material above the optically active layer.

20. A light emitting diode device having a semiconductor element comprising:
a plurality of nanostructures that extend from a substrate, each nanostructure comprising:
a generally longitudinal nanostructure body formed of a semiconductor material and having a proximal end portion of a first crystal lattice structure and a distal end portion, opposite the proximal end portion, of a second crystal lattice structure that is expanded relative to the proximal end portion;
an optically active material optically associated with the distal end portion to form a heterojunction therebetween;
a layer of a semiconductor material disposed over the distal end portions of the nanostructures to form a continuous nanostructured contact surface on the semiconductor element; and
a pair of electrodes, one of the electrodes being electrically coupled to the continuous nanostructured contact surface and the other electrode being electrically coupled to the semiconductor material of the nanostructure body.
